(19) United States
(12) Patent Application Publication
(10) Pub. No.: US 2015/0116178 A1
(43) Pub. Date: Apr. 30, 2015

(54) COMBINED RADIO FREQUENCY IDENTIFICATION (RFID) AND WIRELESS CHARGING ELECTROMAGNETIC WAVE ABSORBER, COMBINED RFID AND WIRELESS CHARGING WIRELESS ANTENNA INCLUDING SAME, AND METHOD FOR MANUFACTURING SAME

(71) Applicant: NANOMAG CO., LTD., Ansan-si, Gyeonggi-do (KR)

(72) Inventors: Ki Hun Kim, Ansan-si (KR); Yong Bok Park, Ansan-si (KR)

(21) Appl. No.: 14/384,416

(22) PCT Filed: Dec. 20, 2012
(86) PCT No.: PCT/KR2012/011166

§ 371 Date: Sep. 11, 2014

(30) Foreign Application Priority Data
Mar. 13, 2012 (KR) 10-2012-0025417

(51) Int. Cl. H01Q 1/52; H05K 9/00; H05K 3/00; H02J 7/02

(52) U.S. Cl. CPC H01Q 1/521; H01Q 1/526; H02J 7/025; H05K 9/0088; H05K 3/0061
USPC 343/842; 174/390; 29/600

(57) ABSTRACT

A combined RFID and wireless charging electromagnetic wave absorber, a combined RFID and wireless charging wireless antenna including same, and a method for manufacturing same. The electromagnetic wave absorber not only performs separate functions of RFID and wireless charging and provides stable operating characteristics, but also has a structure in which an electromagnetic wave absorber and a wireless antenna are integrally coupled so as to maximize the respective performance thereof. Despite a structure in which the two functions of RFID and wireless charging are combined, the thickness of the antenna can be reduced, such that it can be very useful when adopted in and applied to a mobile device, thereby contributing greatly to reducing the thickness of a smartphone.

### TECHNICAL FIELD

The present invention relates to a wireless identification and wireless charging electromagnetic wave absorber that can realize a combination of a wireless identification function, such as radio frequency identification (RFID) and near field communication (NFC), and a wireless charging function. More particularly, the present invention relates to a wireless identification and wireless charging electromagnetic wave absorber which can reliably realize a combination of wireless identification and wireless charging functions, improve the performance of the two functions, and contribute to a slim profile of mobile devices by reducing the thickness, a wireless identification and wireless charging antenna including the same, and a method of fabricating the same.

### BACKGROUND ART

Generally, radio frequency identification (hereinafter referred to as “RFID”) refers to a technology for identifying information stored in an electronic tag without contact using an antenna and a reader via radio waves.

RFID technology allows information to be identified not only within a short distance but also at a long distance using radio waves, typically, a frequency band of 13.56 MHz. A frequency band ranging from 120 to 140 kHz or from 868 to 956 MHz is also used in some cases.

In addition, near field communication (hereinafter referred to as “NFC”), one example technology of RFID application, has been newly devised and is gaining attention as a next-generation technology along with the distribution of smartphones. NFC is a technology with which terminals can transmit and receive data to and from each other within a short distance at a frequency band of 13.56 MHz using a non-contact near distance radio communication module. NFC technology allows data transmission between terminals at a short distance of 10 cm. NFC technology supports bidirectional communication, i.e. information can be not only read but also written. NFC technology enables mobile payment, file sharing, ticket reservation making or advance ticketing.

In particular, NFC technology can be applied not only to payment, but also to a variety of fields, such as transmission of information about goods at supermarkets or shops, transmission of travel information for visitors, traffic and access control lock devices. NFC technology significantly expands the applicability of smartphones.

Mobile devices, such as smartphones on which an antenna for wireless identification, such as RFID or NFC, is mounted are electronics of a high-density circuit to which components are integrated. As the possibility of electromagnetic waves to occur or be induced is increasing, electromagnetic waves may be a cause of deterioration of the performance of mobile devices by disturbing communication for the wireless identification of information, such as RFID or NFC. Therefore, an electromagnetic wave absorber is attached to an RFID or NFC antenna which is mounted on a mobile device. The electromagnetic wave absorber serves to reduce the interference of electromagnetic waves by blocking or absorbing electromagnetic waves, thereby improving the performance of wireless identification.

In addition, along with the introduction of smartphones or the like, there are attempts to combine wireless charging technology to smartphones in order to further improve the convenience of users.

The wireless charging technology is intended to charge a battery using electromagnetic waves without connecting a mobile device charger to an electric socket. When houses, offices and hotels are equipped with an electric energy transceiver, electromagnetic waves output from this device carry electric energy to a mobile device. Therefore, it is possible to charge the mobile device at any time and in any place. The wireless charging technology generally uses a frequency band of 200 kHz.

For this, a mobile device must be equipped with a wireless charging antenna having a coil or a pattern circuit which receives electromagnetic waves for wireless charging. It is also preferred that an electromagnetic wave absorber is attached to the wireless charging antenna in order to increase the performance of wireless charging.

Here, the frequency characteristics of the electromagnetic wave absorber which is combined with the wireless charging antenna differs from the frequency characteristics of the electromagnetic wave absorber which is combined with the wireless identification antenna. Therefore, the material and composition of one electromagnetic wave absorber may differ from the material and composition of the other electromagnetic wave absorber.

A series of recent technological studies and attempts has been made to allow a mobile device such as a smartphone to be equipped with and use both the wireless identification function, such as RFID and NFC, and the wireless charging function. However, it is not easy to put any of these studies and attempts into practical use due to several restrictions, and none of these studies and attempts has arrived at a practical step.

In addition, when the wireless identification technology and the wireless charging technology are simply combined, mutual interference is unavoidable and one of the two technologies must suffer from lower performance and efficiency. It is therefore difficult to satisfy the requirements of both of the technologies, and the simply-combined structure has a significantly-increased thickness, which is an obstacle to maintaining the desired slim profile of smartphones.

### DISCLOSURE

### Technical Problem

Accordingly, the present invention has been made keeping in mind the above problems occurring in the prior art, and an object of the present invention is to provide a wireless identification and wireless charging electromagnetic wave absorber which can reliably realize a combination of a wireless identification function, such as radio frequency identification (RFID) and near field communication (NFC), and a wireless charging function without interference between the different functions, improve the performance of the two functions, and contribute to a slim profile of mobile devices by reducing the thickness, a wireless identification and wireless charging antenna including the same, and a method of fabricating the same.

### Technical Solution

In order to accomplish the above object(s), the present invention provides a wireless identification and wireless charging electromagnetic wave absorber that includes: a first absorbing sheet which blocks and absorbs electromagnetic waves to improve a wireless identification function, including radio frequency identification (RFID) and near field communication (NFC); and a second absorbing sheet which blocks and absorbs electromagnetic waves to improve the wireless identification function, wherein the second absorbing sheet is positioned inside and coplanar with the first absorbing sheet, whereby the thickness of the electromagnetic wave absorber is reduced.

Also provided is a wireless identification and wireless charging antenna that includes: a wireless identification and wireless charging electromagnetic wave absorber including first and second absorbing sheets which block and absorb electromagnetic waves; and a sheet-shaped flexible antenna laminated on a top surface of the wireless identification and wireless charging electromagnetic wave absorber, wherein the flexible antenna comprising a wireless identification antenna pattern which enables wireless identification, such as radio frequency identification (RFID) and near field communication (NFC), and a wireless charging antenna pattern which enables wireless charging, the wireless identification antenna pattern being positioned over the first absorbing sheet, and the wireless charging antenna pattern being positioned over the second absorbing sheet.

Also provided is a method of fabricating a wireless identification and wireless charging electromagnetic wave absorber. The method includes the following steps of: preparing a first absorbing sheet which blocks and absorbs electromagnetic waves to improve wireless identification, such as radio frequency identification (RFID) and near field communication (NFC), by forming an accommodation hole in a central portion of the first absorbing sheet by cutting through the central portion; preparing a second absorbing sheet which blocks and absorbs electromagnetic waves to improve wireless charging, the second absorbing sheet being configured to be disposed over and fitted into the accommodation hole of the first absorbing sheet, the second absorbing sheet being distanced from the first absorbing sheet, thereby defining a space therebetween; coupling the second absorbing sheet with the first absorbing sheet such that the second absorbing sheet is disposed coplanar with the first absorbing sheet by fitting the second absorbing sheet into the accommodation hole of the first absorbing sheet; and laminating a protective sheet on bottom surfaces of the first and second absorbing sheets, which are disposed coplanar and coupled with each other, the protective sheet functioning to enhance a coupling force and protect the first and second absorbing sheets, wherein the protective sheet comprises one selected from the group consisting of a double-sided tape, a polyimide film, a polyethylene terephthalate film, a polycarbonate film, a polypropylene film and a silicone film.

Also provided is a method of fabricating a wireless identification and wireless charging antenna that includes the following steps of: preparing a first absorbing sheet which blocks and absorbs electromagnetic waves to improve wireless identification, such as radio frequency identification (RFID) and near field communication (NFC), by forming an accommodation hole in a central portion of the first absorbing sheet by cutting through the central portion; preparing a second absorbing sheet which blocks and absorbs electromagnetic waves to improve wireless charging, the second absorbing sheet being configured to be disposed over and fitted into the accommodation hole of the first absorbing sheet, the second absorbing sheet being distanced from the first absorbing sheet, thereby defining a space therebetween; coupling the second absorbing sheet with the first absorbing sheet such that the second absorbing sheet is disposed coplanar with the first absorbing sheet by fitting the second absorbing sheet into the accommodation hole of the first absorbing sheet; laminating a protective sheet on bottom surfaces of the first and second absorbing sheets, which are disposed coplanar and coupled with each other, the protective sheet functioning to enhance a coupling force and protect the first and second absorbing sheets; and laminating a sheet-shaped flexible antenna on top surfaces of the first and second absorbing sheets, which are disposed coplanar and coupled with each other, wherein the flexible antenna comprises a wireless identification antenna pattern which enables wireless identification, such as radio frequency identification (RFID) and near field communication (NFC), and a wireless charging antenna pattern which enables wireless charging, the wireless charging antenna pattern being formed at a position divided from the wireless identification antenna pattern, the wireless identification antenna pattern being positioned over the first absorbing sheet, and the wireless charging antenna pattern being positioned over the second absorbing sheet, wherein the protective sheet comprises one selected from the group consisting of a double-sided tape, a polyimide film, a polyethylene terephthalate film, a polycarbonate film, a polypropylene film and a silicone film.

### Advantageous Effects

The present invention as set forth above can realize the availability of providing an electromagnetic wave absorber that has practicability capable of realizing a combination of a wireless identification function, such as radio frequency identification (RFID) and near field communication (NFC), and a wireless charging function and an antenna including the same.

More particularly, both of different functions for wireless identification and wireless charging can be satisfied to realize reliable operational characteristics, and the electromagnetic wave absorber and the antenna are integrally coupled to maximize their own performance and realize reliability. Due to the structural design in which the first absorbing sheet intended to improve the function of wireless identification and the second absorbing sheet intended to improve the function of wireless charging are disposed coplanar, it is possible to reduce the thickness while combining the two functions. The present invention can be significantly useful when employed in and applied to mobile devices and contribute to reduction in the thickness of mobile devices.

### DESCRIPTION OF DRAWINGS

FIG. 1 is a configuration view illustrating a wireless identification and wireless charging electromagnetic wave absorber according to an embodiment of the present invention;

FIG. 2 is a cross-sectional view illustrating the protective sheet of the wireless identification and wireless charging electromagnetic wave absorber according to an embodiment of the present invention;

FIG. 3 is a cross-sectional view illustrating a wireless identification and wireless charging electromagnetic wave absorber according to another embodiment of the present invention;

FIG. 4 is a cross-sectional view illustrating a wireless identification and wireless charging electromagnetic wave absorber according to a further embodiment of the present invention;

FIG. 5 is a configuration view illustrating an wireless identification and wireless charging antenna according to an embodiment of the present invention in which an wireless identification and wireless charging electromagnetic wave absorber is integrally combined;

FIG. 6 is a top-plan view illustrating an wireless identification and wireless charging antenna in which the wireless identification and wireless charging electromagnetic wave absorber according to an embodiment of the present invention is integrally combined;

FIG. 7 is a cross-sectional view illustrating an wireless identification and wireless charging antenna in which the wireless identification and wireless charging electromagnetic wave absorber according to an embodiment of the present invention is integrally combined;

FIG. 8 is a cross-sectional view illustrating another embodiment of the wireless identification and wireless charging antenna according to the present invention in which the wireless identification and wireless charging electromagnetic wave absorber is integrally combined;

FIG. 9 is a cross-sectional view illustrating a further embodiment of the wireless identification and wireless charging antenna according to the present invention in which the wireless identification and wireless charging electromagnetic wave absorber is integrally combined; and

FIG. 10 is a flowchart illustrating a method of fabricating a wireless identification and wireless charging electromagnetic wave absorber antenna according to an embodiment of the present invention and a wireless identification and wireless charging wireless including the same.

### BEST MODE

Reference will now be made in greater detail to exemplary embodiments of the present invention, examples of which are illustrated in the accompanying drawings. The object and constitution of the present invention as well as their features will be more apparent from the following detailed description.

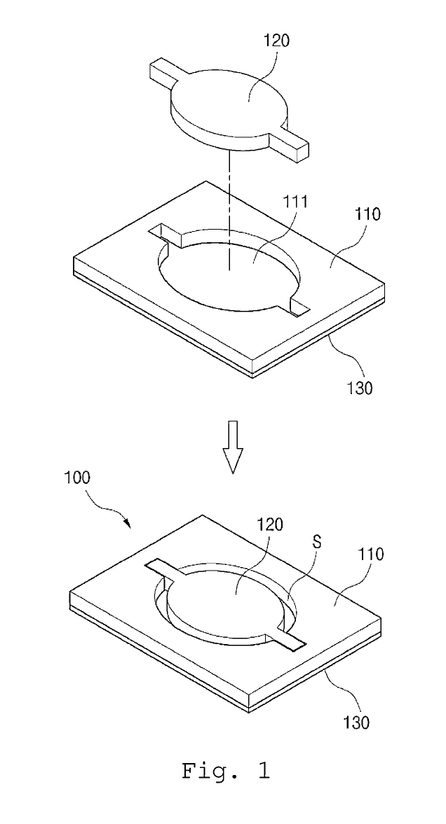

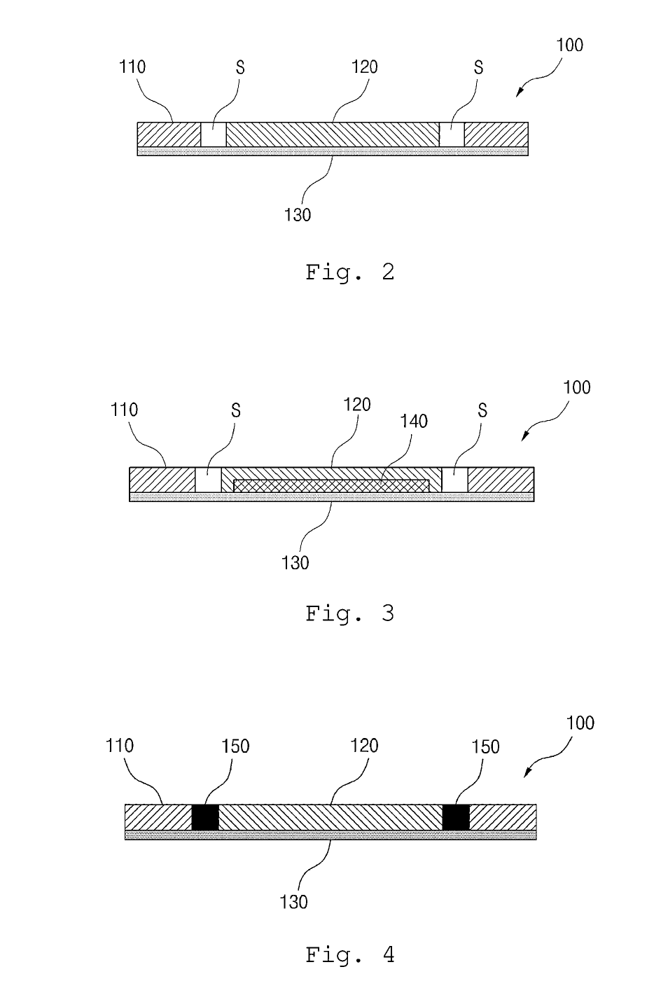

As shown in FIG. 1 to FIG. 4, an wireless identification and wireless charging electromagnetic wave absorber 100 according to an exemplary embodiment of the present invention includes a first absorbing sheet 110 which blocks and absorbs electromagnetic waves in order to improve a wireless identification function, such as radio frequency identification (RFID) and near field communication (NFC), and a second absorbing sheet 120 which blocks and absorbs electromagnetic waves in order to improve the wireless identification function. The second absorbing sheet 120 is positioned inside and coplanar with the first absorbing sheet 110.

The first absorbing sheet 110 has an accommodation hole 111 which is formed in the central portion of the first absorbing sheet 110 by a suitable cutting process such that the second absorbing sheet 120 can be disposed inside and coplanar with the first absorbing sheet 110. With this configuration, the second absorbing sheet 120 can be fitted into the accommodation hole 111 of the first absorbing sheet 110.

The accommodation hole 111 and the second absorbing sheet 120 are preferably machined by punching in consideration of productivity and working efficiency. The accommodation hole 111 and the second absorbing sheet 120 can be machined by cutting using, for example, a laser or a numerical control/computerized numerical control (NC/CNC) machine.

In addition, although the accommodation hole 111 of the first absorbing sheet 110 and the second absorbing sheet 120 can have a fitting structure in which one completely conforms with the other, a structure in which the outer portions of one component are fitted into the corresponding portions of the other component is more preferably provided, as shown in the figures. With this configuration, when the second absorbing sheet 120 is fitted into the accommodation hole 111 of the first absorbing sheet 110, spaces S are defined between the inner circumference of the accommodation hole 111 and the outer circumference of the second absorbing sheet 120.

It is preferred that the width of the spaces S defined between the inner circumference of the accommodation hole 111 of the first absorbing sheet 110 and the outer circumference of the second absorbing sheet 120 range from 2 to 5 mm. The spaces S are formed in order to effectively prevent magnetic fields generated from the first absorbing sheet 110 and the second absorbing sheet 120 from invading each other's areas to interfere with and cause a loss to each other.

In other words, it is intended to disconnect either a flow of electromagnetic field for blocking or absorbing electromagnetic waves or a flow of electromagnetic waves to be absorbed to the absorbing sheets. This effect can prevent magnetic fields or electromagnetic waves from one sheet from flowing to the other sheet that would otherwise cause interference or disturbance, thereby enhancing the different functions of the two sheets.

When the width of the spaces S is less than 2 mm, the magnetic fields may interfere with and cause a loss to each other, thereby degrading performance. When the width of the spaces S is greater than 5 mm, it may be difficult to form one of the fitting and corresponding portions of the first and second absorbing sheet, the efficiency of blocking and absorbing electromagnetic waves of one of the first and second absorbing sheet may be lowered, or the space in which an antenna is to be disposed may be narrow.

Furthermore, a synthetic resin having a low dielectric constant, such as polyvinyl chloride (PVC), polypropylene (PP), ethylene-vinyl acetate (EVA) and fibre-reinforced plastic (FRP), may be contained in the spaces S between the first absorbing sheet 110 and the second absorbing sheet 120 to form a blocking layer 150 which can prevent the magnetic fields generated from the first absorbing sheet 110 and the second absorbing sheet 120 from invading each other's areas to interfere with and cause a loss to each other.

The first absorbing sheet 110 can be made of any one of known electromagnetic absorbing materials for wireless identification (e.g. RFID and NFC) including an electromagnetic absorbing material produced by mixing electromagnetic wave absorbing magnetic powder and a binder.

The magnetic powder used for the first absorbing sheet 110 may be a metal-based ferromagnetic material, a typical example of which is iron, an alloy containing iron or a mixture thereof; an oxide-based ferromagnetic material, a typical example of which is ferrite; or a mixture thereof.

The second absorbing sheet 120 can also be made of any one of known electromagnetic absorbing materials for wireless identification including an electromagnetic absorbing material produced by mixing electromagnetic wave absorbing magnetic powder and a binder.

The magnetic powder used for the second absorbing sheet 120 may be iron or an alloy containing iron, examples of which are Fe, Fe—Si alloys, Fe—Al alloys, Fe—Ni alloys, Fe—Al—Si alloys, Fe—B—Si alloys and Fe—Co—Ni alloys, or a mixture thereof.

Herein, it is not intended to limit the first and second absorbing sheet 110 and 120 to the above-mentioned foregoing embodiment but a variety of materials distributed in the market or known in the art can be applied to the first and second absorbing sheet 110 and 120.

In addition, a protective sheet 130 may be provided, for example, laminated on the bottom surfaces of the first absorbing sheet 110 and second absorbing sheet 120 which are disposed coplanar.

The protective sheet 130 enhances the coupling force between the first absorbing sheet 110 and the second absorbing sheet 120, which are coupled to each other in a fitting fashion, in order to increase endurance, serves as a coupling structure with which the electromagnetic wave absorber 100 can be easily coupled to a mobile device such as a smartphone, and protects the electromagnetic wave absorber 100 from external factors, such as heat, moisture and humidity. Different materials may be applied according to whether the protective sheet 130 is attached to a battery side or a case side of the mobile device.

For example, the protective sheet 130 can be implemented as a double-sided tape having a release paper when the protective sheet 130 is attached to the battery side of a mobile device. The protective sheet 130 can be implemented as a film made of one selected from among polyimide (PI), polyethylene terephthalate (PET), polycarbonate (PC), polypropylene (PP) and silicone when the protective sheet 130 is attached to the case side of a mobile device.

In addition, an iron sheet 140 is disposed on the bottom surface of the second absorbing sheet 120. This configuration can remove eddy current loss caused by the formation of a magnetic field, thereby improving the efficiency and performance of wireless charging. The thickness of the iron sheet 140 does not exceed the thickness of the second absorbing sheet 120 in order to realize that the configuration is suitable and reduce the thickness. It is preferred that the iron sheet 140 is disposed on the bottom surface before the protective sheet 130 is laminated on the bottom surface.

Furthermore, although not shown, a heat dissipation sheet may be disposed on the bottom surface of the second absorbing sheet 120 as an alternative to the iron sheet 140 in order to achieve a heat dissipation effect.

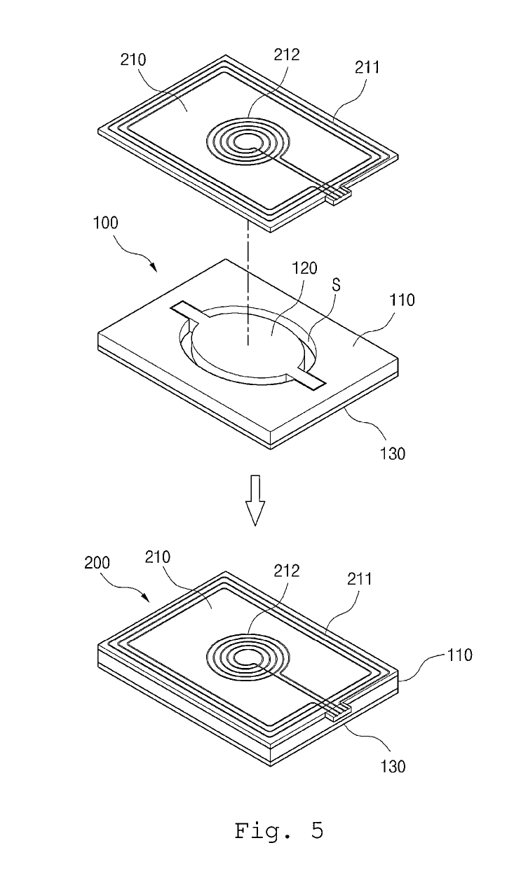

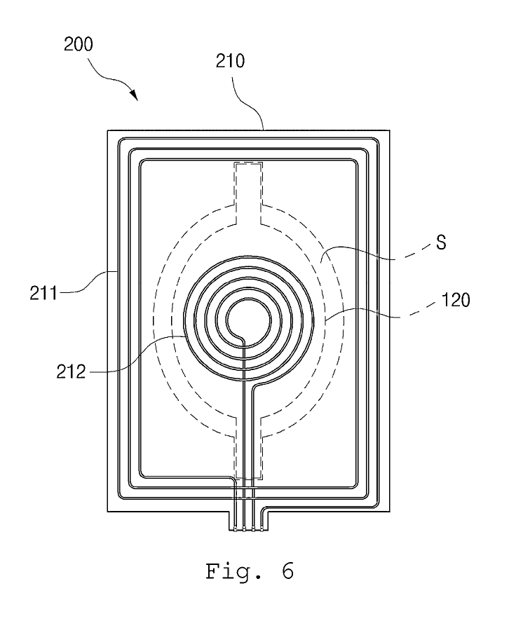

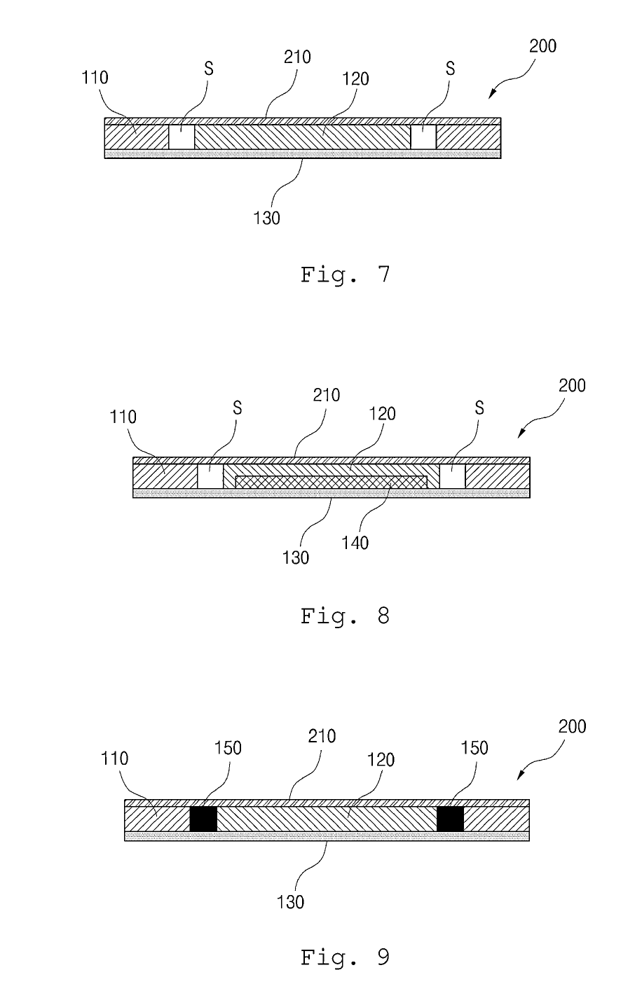

As shown in FIG. 5 to FIG. 9, an wireless identification and wireless charging antenna 200 according to an embodiment of the present invention includes the sheet-shaped wireless identification and wireless charging electromagnetic wave absorber 100 and a sheet-shaped flexible antenna 210 laminated on the top surface of the wireless identification and wireless charging electromagnetic wave absorber 100. In the sheet-shaped wireless identification and wireless charging electromagnetic wave absorber 100, the first absorbing sheet 110 and the second absorbing sheet 120 are coupled with each other and disposed coplanar due to the cutting process. The sheet-shaped flexible antenna 210 includes a Wireless identification antenna pattern 211 which enables wireless identification, such as RFID or NFC, and a wireless charging antenna pattern 212 which enables wireless charging. The Wireless identification antenna pattern 211 is positioned over the first absorbing sheet 110, and the wireless charging antenna pattern 212 is positioned over the second absorbing sheet 120.

Here, the flexible antenna 210 may be implemented as a sheet-shaped flexible antenna in which a conductive antenna pattern is formed by printing, such as silk printing, ink printing or laser printing, or etching a conductive material, such as copper (Cu) or silver (Ag). The printing is more preferable considering productivity and reduction in thickness.

The Wireless identification antenna pattern 211 and the wireless charging antenna pattern 212 are formed independent from each other at positions that are divided from each other.

It is to be understood that the Wireless identification antenna pattern 211 and the wireless charging antenna pattern 212 use different frequency bands.

Here, the wireless identification and wireless charging electromagnetic wave absorber 100 and the flexible antenna 210, which includes the two antenna patterns, can be laminated on each other by a variety of means such as an adhesive, a double-sided tape, laminating or thermal pressing.

In addition, as described above, the wireless identification and wireless charging electromagnetic wave absorber 100 may have a configuration in which the protective sheet 130 which increases the force of coupling the first absorbing sheet 110 and the second absorbing sheet 120 to each other is laminated. The protective sheet 130 can protect the electromagnetic wave absorber 100 as well as the wireless identification and wireless charging flexible antenna 210 from external factors, such as heat, moisture and humidity.

Furthermore, as described above, the wireless identification and wireless charging electromagnetic wave absorber 100 may be selectively provided with the iron sheet 140 or the heat dissipation sheet on the bottom surface of the second absorbing sheet 120 where the wireless charging antenna pattern 212 is located. The iron sheet 140 removes eddy current loss caused by the formation of a magnetic field, thereby improving frequency efficiency and performance for wireless charging. The heat dissipation sheet serves to dissipate heat.

In addition, as described above, the wireless identification and wireless charging electromagnetic wave absorber 100 may have the blocking layer 150 which is made of a synthetic resin having a low dielectric constant, such as polyvinyl chloride (PVC), polypropylene (PP), ethylene-vinyl acetate (EVA) and fibre-reinforced plastic (FRP), which is disposed in the spaces S defined between the first absorbing sheet 110 and the second absorbing sheet 120.

Herein, the wireless identification and wireless charging electromagnetic wave absorber 100 will not be described in further detail since the structure and the design thereof are equivalent to those of the above-described electromagnetic wave absorber.

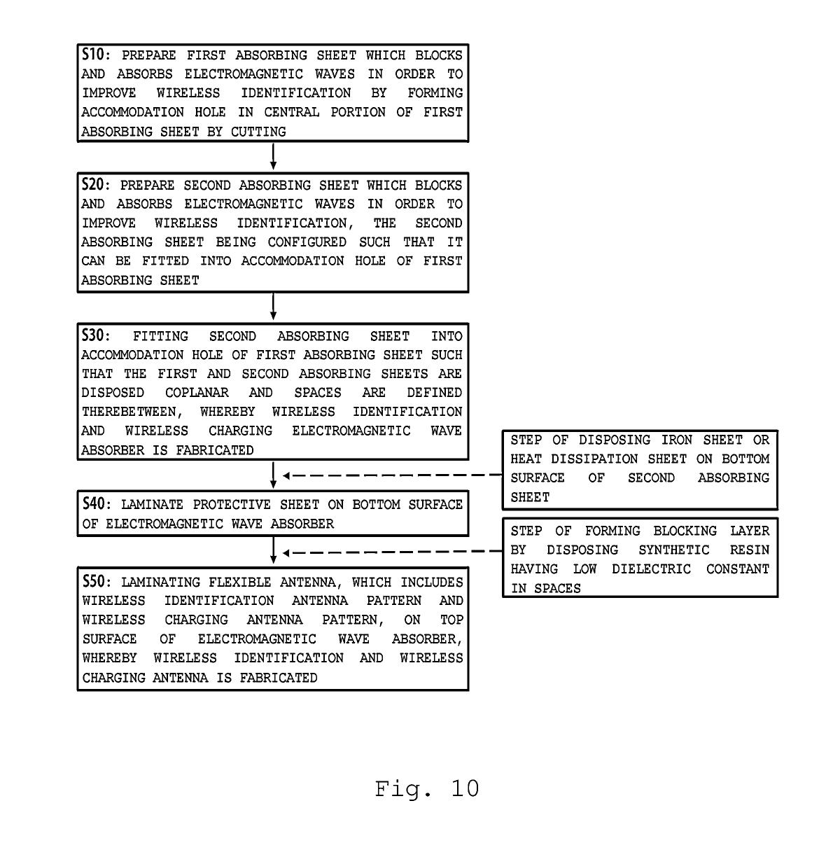

With reference to FIG. 10, a description will be given to a method of fabricating the wireless identification and wireless charging electromagnetic wave absorber 100 and the wireless identification and wireless charging antenna 200 including the electromagnetic wave absorber 100 according to the present invention, the configurations of which were described above.

A first absorbing sheet 110 which blocks and absorbs electromagnetic waves in order to improve a wireless identification function, such as RFID or NFC, is prepared by forming an accommodation hole 111 in the central portion of the first absorbing sheet 110 by cutting through the central portion (S10).

Here, punching is preferable for the formation of the accommodation hole 111 in consideration of productivity and working efficiency. A cutting process employing a laser or an NC/CNC machine may also be used.

A second absorbing sheet 120 which blocks and absorbs electromagnetic waves in order to improve a wireless charging function is prepared, the second absorbing sheet 120 being configured such that the second absorbing sheet 120 can be fitted into the accommodation hole 111 of the first absorbing sheet 110 in fitting fashion (S20).

Here, although the second absorbing sheet 120 may have a fitting structure that completely conforms with the accommodation hole 111 of the first absorbing sheet 110, a structure in which the outer portions of one component are fitted into the corresponding portions of the other component is more preferably provided. With this configuration, when the second absorbing sheet 120 is fitted into the accommodation hole 111 of the first absorbing sheet 110, spaces S are defined between the inner circumference of the accommodation hole 111 and the outer circumference of the second absorbing sheet 120.

As described above, the width of the spaces S preferably ranges from 2 to 5 mm.

In this case, the second absorbing sheet 120 is also preferably machined by punching in consideration of productivity and working efficiency. A cutting process using, for example, a laser or an NC/CNC machine is also applicable.

Afterwards, second absorbing sheet 120 is fitted into the accommodation hole 111 of the first absorbing sheet 110 such that the first and second absorbing sheets 110 and 120 are disposed coplanar and the spaces S are defined, whereby an wireless identification and wireless charging electromagnetic wave absorber 100 is fabricated (S30).

The first absorbing sheet 110 and the second absorbing sheet 120 conduct different functions in order to improve the performance of wireless identification and wireless charging. Since the first and second absorbing sheets 110 and 120 are designed to be disposed coplanar, the two functions can be combined and the thickness can be reduced regardless of the combination of the first and second absorbing sheets 110 and 120. In addition, since the spaces S are defined between the portions of the first and second absorbing sheets 110 and 120 except for the portions which are coupled with each other, the portions of the first and second absorbing sheets 110 and 120 except for the portions which are coupled with each other can perform their own functions.

Subsequently, at S40, a protective sheet 130 is laminated on the bottom surface of the electromagnetic wave absorber 100, the resultant structure fabricated through the third step S30.

The laminated protective sheet 130 can enhance the coupling force between the first and second absorbing sheets 110 and 120, thereby increasing endurance.

At S50, a sheet-shaped flexible antenna 210 is laminated on the top surface of the electromagnetic wave absorber 100 which is the resultant structure fabricated through the step S40. The flexible antenna 210 includes a Wireless identification antenna pattern 211 which enables wireless identification, such as RFID or NFC, and a wireless charging antenna pattern 212 which enables wireless charging. The sheet-shaped flexible antenna 210 is laminated on the electromagnetic wave absorber 100 such that the Wireless identification antenna pattern 211 is located over the first absorbing sheet 110 and the wireless charging antenna pattern 212 is located over the second absorbing sheet 120. With this process, a wireless identification and wireless charging antenna 200 in which the wireless identification and wireless charging electromagnetic wave absorber 100 is integrally combined is fabricated.

In addition, a step of disposing an iron sheet 140 or a heat dissipation sheet (not shown) on the bottom surface of the second absorbing sheet 120 may be selectively performed. The iron sheet 140 can remove eddy current loss caused by the formation of a magnetic field, thereby improving frequency efficiency and performance for wireless charging. The iron sheet 140 or the heat dissipation sheet may be disposed on the bottom surface after the shaping of the second absorbing sheet 120 or before the attachment of the protective sheet 130.

Furthermore, a step of forming blocking layer 150 can be performed by disposing a synthetic resin having a low dielectric constant, such as polyvinyl chloride (PVC), polypropylene (PP), ethylene-vinyl acetate (EVA) and fibre-reinforced plastic (FRP), in the spaces defined between the first absorbing sheet 110 and the second absorbing sheet 120 of the electromagnetic wave absorber 100. This step is preferably performed after the attachment of the protective sheet 130.

It should be understood that the present invention is not limited to these process steps as forth above. It is apparent that the sequence of the process can be substituted, modified or altered.

### DESCRIPTION OF THE REFERENCE NUMERALS

100: electromagnetic wave absorber
110: first absorbing sheet
111: accommodation hole
120: second absorbing sheet
130: protective sheet
140: iron sheet
150: blocking layer
200: wireless identification and wireless charging antenna
210: flexible antenna
211: wireless identification antenna pattern
212: wireless charging antenna pattern
S: space

### INDUSTRIAL APPLICABILITY

The present invention can satisfy both of different functions for wireless identification and wireless charging to realize reliable operational characteristics as well as provide an integrated structure in which the electromagnetic wave absorber and the antenna are coupled each other to maximize their own performance and realize reliability. It is possible to combine the function of wireless identification and the function of wireless charging as well as to reduce the thickness while combining the two functions. The present invention has industrial applicability in that it is significantly useful when employed in and applied to mobile devices and contributes to reduction in the thickness of mobile devices.

1. A wireless identification and wireless charging electromagnetic wave absorber comprising:
a first absorbing sheet which blocks and absorbs electromagnetic waves to improve a wireless identification function, including radio frequency identification (RFID) and near field communication (NFC); and
a second absorbing sheet which blocks and absorbs electromagnetic waves to improve the wireless identification function, wherein the second absorbing sheet is positioned inside and coplanar with the first absorbing sheet, whereby a thickness of the electromagnetic wave absorber is reduced.

2. The wireless identification and wireless charging electromagnetic wave absorber according to claim 1, wherein the first absorbing sheet has an accommodation hole in a central portion, the accommodation hole comprising a cut in the central portion of the first absorbing sheet, whereby the second absorbing sheet is allowed to be fitted into the accommodation hole and coupled with the first absorbing sheet, and wherein an inner circumference of the accommodation hole of the first absorbing sheet and an outer circumference of the second absorbing sheet are distanced from each other, thereby defining a space therebetween.

3. The wireless identification and wireless charging electromagnetic wave absorber according to claim 2, wherein a width of the space ranges from 2 to 5 mm between the first absorbing sheet and the outer circumference of the second absorbing sheet.

4. The wireless identification and wireless charging electromagnetic wave absorber according to claim 1, further comprising an iron sheet or a heat dissipation sheet selectively disposed on a bottom surface of the second absorbing sheet, wherein the iron sheet removes eddy current loss, thereby improving efficiency and performance of wireless charging, and the heat dissipation sheet achieves a heat dissipation effect.

5. The wireless identification and wireless charging electromagnetic wave absorber according to claim 2, further comprising a blocking layer disposed within the space, the blocking layer being made of a synthetic resin having a low dielectric constant.

6. The wireless identification and wireless charging electromagnetic wave absorber according to claim 1, further comprising a protective sheet laminated on bottom surfaces of the first and second absorbing sheets which are disposed coplanar, the protective sheet functioning to enhance a coupling force between the first and second absorbing sheets and protect the first and second absorbing sheets, wherein the protective sheet comprises one selected from the group consisting of a double-sided tape, a polyimide film, a polyethylene terephthalate film, a polycarbonate film, a polypropylene film and a silicone film.

7. A wireless identification and wireless charging antenna comprising:
the wireless identification and wireless charging electromagnetic wave absorber as recited in claim 1; and
a sheet-shaped flexible antenna laminated on a top surface of the wireless identification and wireless charging electromagnetic wave absorber, wherein the flexible antenna comprising a wireless identification antenna pattern which enables wireless identification, such as radio frequency identification (RFID) and near field communication (NFC), and a wireless charging antenna pattern which enables wireless charging, the wireless identification antenna pattern being positioned over the first absorbing sheet, and the wireless charging antenna pattern being positioned over the second absorbing sheet.

8. A method of fabricating a wireless identification and wireless charging electromagnetic wave absorber, comprising:
preparing a first absorbing sheet which blocks and absorbs electromagnetic waves to improve wireless identification, such as radio frequency identification (RFID) and near field communication (NFC), by forming an accommodation hole in a central portion of the first absorbing sheet by cutting through the central portion;
preparing a second absorbing sheet which blocks and absorbs electromagnetic waves to improve wireless charging, the second absorbing sheet being configured to be disposed over and fitted into the accommodation hole of the first absorbing sheet, the second absorbing sheet being distanced from the first absorbing sheet, thereby defining a space therebetween;
coupling the second absorbing sheet with the first absorbing sheet such that the second absorbing sheet is disposed coplanar with the first absorbing sheet by fitting the second absorbing sheet into the accommodation hole of the first absorbing sheet; and
laminating a protective sheet on bottom surfaces of the first and second absorbing sheets, which are disposed coplanar and coupled with each other, the protective sheet functioning to enhance a coupling force and protect the first and second absorbing sheets,
wherein the protective sheet comprises one selected from the group consisting of a double-sided tape, a polyimide film, a polyethylene terephthalate film, a polycarbonate film, a polypropylene film and a silicone film.

9. The method according to claim 8, wherein the accommodation hole of the first absorbing sheet and the second absorbing sheet are formed by punching or cutting.

10. The method according to claim 8, wherein an iron sheet or a heat dissipation sheet is disposed on the bottom surface of the second absorbing sheet.

11. The method according to claim 8, wherein a blocking layer is formed within the space between the first and second absorbing sheets by disposing a synthetic resin having a low dielectric constant in the space.

12. A method of fabricating a wireless identification and wireless charging antenna comprising:
preparing a first absorbing sheet which blocks and absorbs electromagnetic waves to improve wireless identification, such as radio frequency identification (RFID) and near field communication (NFC), by forming an accommodation hole in a central portion of the first absorbing sheet by cutting through the central portion;
preparing a second absorbing sheet which blocks and absorbs electromagnetic waves to improve wireless charging, the second absorbing sheet being configured to be disposed over and fitted into the accommodation hole of the first absorbing sheet, the second absorbing sheet being distanced from the first absorbing sheet, thereby defining a space therebetween;
coupling the second absorbing sheet with the first absorbing sheet such that the second absorbing sheet is disposed coplanar with the first absorbing sheet by fitting the second absorbing sheet into the accommodation hole of the first absorbing sheet;
laminating a protective sheet on bottom surfaces of the first and second absorbing sheets, which are disposed coplanar and coupled with each other, the protective sheet functioning to enhance a coupling force and protect the first and second absorbing sheets; and
laminating a sheet-shaped flexible antenna on top surfaces of the first and second absorbing sheets, which are disposed coplanar and coupled with each other, wherein the flexible antenna comprises a wireless identification antenna pattern which enables wireless identification, such as radio frequency identification (RFID) and near field communication (NFC), and a wireless charging antenna pattern which enables wireless charging, the wireless charging antenna pattern being formed at a position divided from the wireless identification antenna pattern, the wireless identification antenna pattern being positioned over the first absorbing sheet, and the wireless charging antenna pattern being positioned over the second absorbing sheet,
wherein the protective sheet comprises one selected from the group consisting of a double-sided tape, a polyimide film, a polyethylene terephthalate film, a polycarbonate film, a polypropylene film and a silicone film.

13. The method according to claim 12, wherein an iron sheet or a heat dissipation sheet is disposed on the bottom surface of the second absorbing sheet.

14. The method according to claim 12, wherein a blocking layer is formed within the space between the first and second absorbing sheets by disposing a synthetic resin having a low dielectric constant in the space.

15. The method according to claim 12, wherein the accommodation hole of the first absorbing sheet and the second absorbing sheet are formed by punching or cutting.
